(19) United States
(12) Patent Application Publication
(10) Pub. No.: US 2016/0054125 A1
(43) Pub. Date: Feb. 25, 2016

(54) BATTERY COMPARTMENT SCREEN

(71) Applicant: STEINER-OPTIK GMBH, Bayreuth (DE)

(72) Inventor: Matthias HOFMANN, Bayreuth (DE)

(73) Assignee: STEINER-OPTIK GmbH, Bayreuth (DE)

(21) Appl. No.: 14/781,254

(22) PCT Filed: Apr. 16, 2014
(86) PCT No.: PCT/DE2014/000196

§ 371 Date: Sep. 29, 2015

(30) Foreign Application Priority Data
Apr. 18, 2013 (DE) 20 2013 003 631.1

(51) Int. Cl. G01C 17/38; H05K 9/00; G01R 33/00; G02B 23/16; G02B 7/02

(52) U.S. Cl. CPC G01C 17/38; G02B 23/16; G02B 7/02; G01R 33/0076; H05K 9/0075

(57) ABSTRACT

Optically magnifying apparatus, in particular monocular or binocular telescope or field glasses (1) or the like, having a housing (2) with at least one lens barrel (4) for accommodating optical elements (5), a compass device (6) which is arranged in the housing (2), at least one electronic device which is arranged in the housing (2), and at least one accommodation region (7) for at least one power source in the form of a battery (8) or the like, wherein the accommodation region (7) for the power source (8) or the power source (8) itself comprises a screening device (10) which acts against a magnetic sensor (9) of the compass device (6).

The invention relates to an optically magnifying apparatus, in particular a pair of monocular or binocular field glasses or a monocular or binocular telescopic sight, night vision device, rangefinder or the like, having a housing with at least one lens barrel for accommodating optical elements, a compass device which is arranged in the housing, at least one electronic device which is arranged in the housing, and at least one accommodation region for at least one power source in the form of a battery or the like.

Said invention therefore concerns the area of field glasses or telescopes which comprise any kind of electrical device and a compass device, wherein the compass device itself can also form the electrical device. However, optical apparatuses with electronic devices such as, for example, illuminated reticles, illuminated division scales, image amplifiers, electronic display elements and the like, are also intended to be covered by said term.

An accommodation region for a battery or the like is provided in order to be able to supply electrical power to such electronic devices or electronic compasses, illuminated reticles, illumination elements and the like.

Depending on their design, batteries can generate disturbing magnetic fields which can have a disadvantageous effect on the accuracy of the display of a mechanical or electronic compass in the optically magnifying apparatus.

The invention is based on the object of designing an apparatus having the features of the preamble of claim 1 in such a way that these kinds of negative influences of a power source on a compass are avoided. This object is achieved by the characterizing features of claim 1, and advantageous developments can be found in dependent claims 2-15.

The essence of the invention is considered to be that of providing a screening device which is concentrated on the accommodation region for the power source or the power source itself. As a result, the compass, which is usually arranged at a certain distance from the power source, in the apparatus remains uninfluenced by disturbing magnetic fields which can be generated by the magnetic fields of the battery or in conjunction with the screening device.

In each case, the screening device is designed such that the Earth's magnetic field is not influenced at the position of the magnetic sensor of the compass.

The screening device is advantageously designed such that the magnetic field lines of the power source are prevented from exiting from the accommodation region by the screening device, wherein the accommodation region is advantageously matched to the outer shape of the at least one power source, and the screening device is arranged between the inner wall of the accommodation region and the outer wall of the power source.

A particularly compact screening device is produced when the screening device is in the form of a housing element which accommodates the battery and is composed of a magnetically screening metal, in particular μ-metal. The screening device can be in the form of a screening sleeve, in particular μ-metal sleeve, which has an open end. This has the advantage that batteries with lengths which differ slightly from one another can then be inserted into the screening sleeve between its poles, without having a negative influence on the contact-connection or the screening. To this end, the closed end of the screening sleeve can be electrically conductively connected to a connection element in the accommodation region, wherein either a permanent connection to a cable or a contact-making connection which is closed when the screening sleeve is inserted into the battery compartment and is pressed against an end-side contact in the battery compartment by way of a contact-pressure spring is possible.

The accommodation region is advantageously cylindrical and provided for accommodating a cylindrical battery, and an open end of the accommodation region is designed such that it can be closed by a screw cap. The screening sleeve is mounted in an accommodation region of this kind in a longitudinally displaceable manner and prestressed in the direction of the screw cap by the connection element which is in the form of a spring.

In a development of the invention, it is possible to also provide the screw cap with a screening cap element which engages over the end of the screening sleeve.

A first pole of the battery which is inserted into the screening element makes electrical contact with the inner closed end of the accommodation cap, and a second, opposite pole of the battery makes contact with at least one contact projection of the screw cap or the screening cap element.

The screening cap element can engage over approximately 10-50% of the length of the screening sleeve, as a result of which particularly effective magnetic screening is ensured.

The invention is explained in greater detail with reference to advantageous exemplary embodiments in the drawing figures, in which:

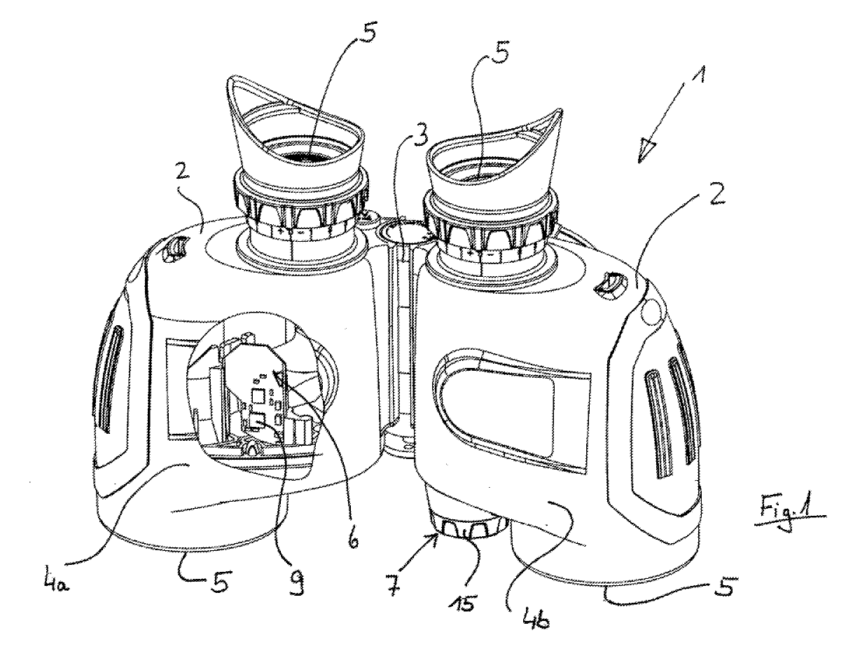

FIG. 1: shows an illustration of a pair of field glasses having a partially broken-open lens barrel, illustrated on the left-hand side, with an integrated magnetic sensor of an electronic compass and having an accommodation region for a battery in the lens barrel illustrated on the right-hand side;

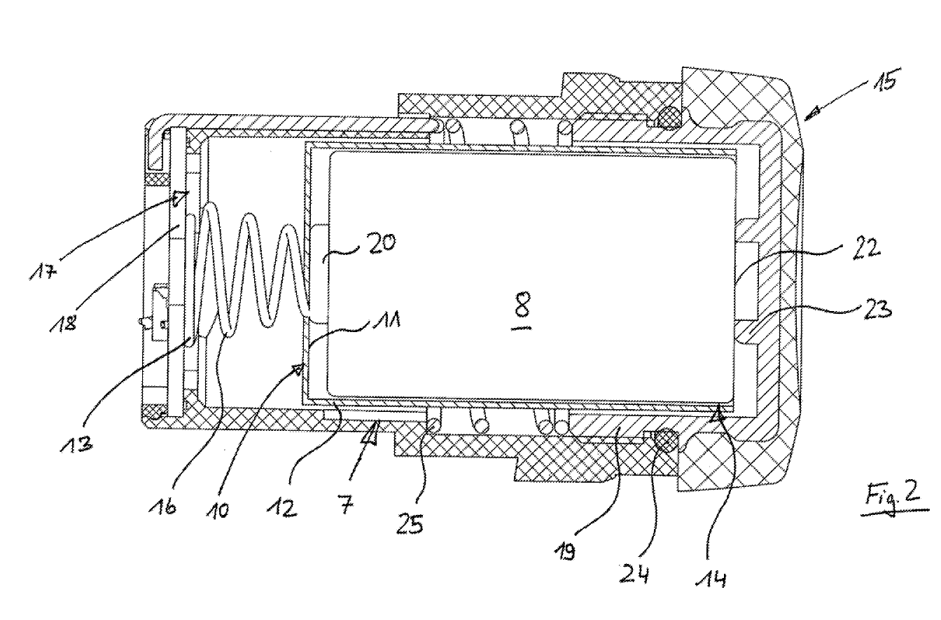

FIG. 2: shows a longitudinal sectional illustration through an accommodation region for at least one power source of an optically magnifying apparatus with screening device and battery inserted;

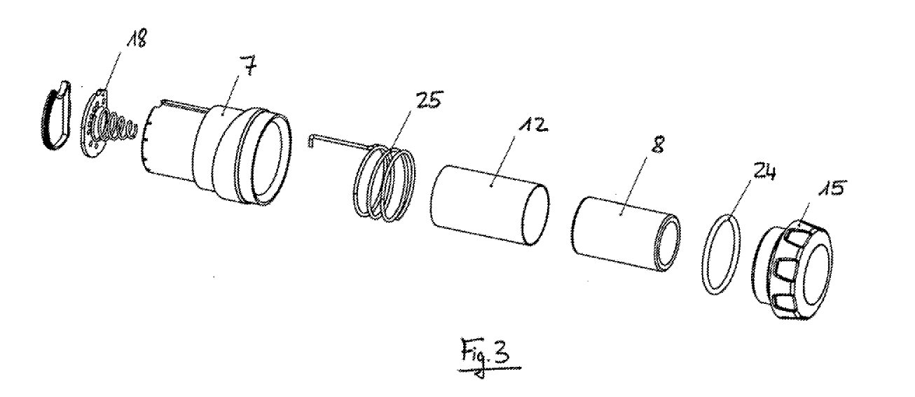

FIG. 3: shows an exploded perspective illustration of the important components of the accommodation apparatus and the elements inserted into it.

Drawing FIG. 1 shows an optically magnifying apparatus in the form of a pair of binocular field glasses 1, the housing 2 of said field glasses having lens barrels 4, which can be pivoted in relation to one another by means of an articulated connection 3, for accommodating optical elements 5 which are only partially visible in the drawing figures.

An electronic compass device, which therefore represents an electronic device, is arranged in the lens barrel 4a. An accommodation region 7, which can be closed, for a battery 8 for supplying power to the electronic device, specifically to the compass device 6, is provided in the lens barrel 4b.

As is particularly clear from FIGS. 2 and 3, the accommodation region 7 for the power source 8 is provided with a screening device 10 which acts against the magnetic sensor 9 of the compass device 6. The screening device 10 is designed and arranged such that the Earth's magnetic field is not influenced at the position of the magnetic sensor 9. The magnetic field lines, not illustrated, which the power source, specifically the battery 8, can generate are prevented from exiting from the accommodation region 7 by the screening device 10 and therefore cannot cause declination of the electronic compass device 6. The same also applies when the compass device 6 is in the form of a normal magnetic compass; it is also necessary to ensure in this case that a field which is generated by the battery 8 does not have an adverse effect on the functioning of the compass.

In the present case, the accommodation region 7 is matched to the outer shape of the power source, specifically the battery 8, and the screening device 10 is arranged between the inner wall of the accommodation region 7 and the outer wall of the power source 8. Overall, the screening device 10 is in the form of a housing element which accommodates the battery 8, specifically a screening sleeve which is composed of magnetically screening material, in particular μ-metal. The closed end 11 of the screening sleeve 12 is electrically conductively connected to a connection element 13 in the accommodation region 7. An open end 14 of the accommodation region 7 can be closed by a screw cap 15. The screening cap is prestressed against the force of a spring 16 in the bottom region 17 of the accommodation region 7 which also contains a diagnosis plate 18 of the electrical power supply, and is therefore mounted in the accommodation region 7 in a longitudinally displaceable manner. Said screening cap is spring-loaded in the direction of the screw cap 15 by the connection element 13 which is in the form of a spring.

The screw cap 15 has a cap-like element 19 which engages over the end of the screening sleeve 12 and can also serve as a screening cap element 19 if it is formed from an appropriate material.

A first pole 20 of the inserted battery 8 makes contact with the inner closed end 11 of the screening sleeve 12, and at least one contact projection 23 makes contact with a second opposite pole 22 of the battery 8 in the inner region of the screw cap 15.

The screw cap 15 is further provided with a sealing element, in particular with an O-ring seal 24. In the illustrated exemplary embodiment, the screw cap 15 engages over approximately 40% of the length of the inserted screening sleeve 12, the screening sleeve for its part being surrounded at a distance by a contact spring 25 which makes contact with the inner end of the screw cap 15 and therefore connects the pole 22 of the inserted battery 8 to the electronic elements of the diagnosis plate 18 and allows power to be supplied to the electronic components within the pair of field glasses 1.

### LIST OF REFERENCE SYMBOLS

| | |
|---|---|
| 1 | Field glasses |
| 2 | Housing |
| 3 | Articulated connection |
| 4 | Lens barrels |
| 5 | Optical element |
| 6 | Compass device |
| 7 | Accommodation region |
| 8 | Battery |
| 9 | Magnetic sensor |
| 10 | Screening device |
| 11 | Closed end |
| 12 | Screening sleeve |
| 13 | Connection element |
| 14 | Open end |
| 15 | Screw cap |
| 16 | Spring |
| 17 | Bottom region |
| 18 | Diagnosis plate |
| 19 | Element |
| 20 | Pole of 8 |
| 21 | Closed end of 12 |
| 22 | Pole |
| 23 | Contact projection |
| 24 | O-ring seal |
| 25 | Contact spring |

1. An optically magnifying apparatus, in particular monocular or binocular telescope or field glasses (1), having
a housing (2) with at least one lens barrel (4) for accommodating optical elements (5),
a compass device (6) which is arranged in the housing (2),
at least one electronic device which is arranged in the housing (2), and
at least one accommodation region (7) for at least one power source in the form of a battery (8) or the like,
characterized in that the accommodation region (7) for the power source (8) or the power source (8) itself comprises a screening device (10) which acts against a magnetic sensor (9) of the compass device (6).

2. The apparatus as claimed in claim 1, characterized in that the screening device (10) is designed such that the Earth's magnetic field is not influenced at the position of the magnetic sensor (9).

3. The apparatus according to claim 1, characterized in that the magnetic field lines of the power source (8) are prevented from exiting from the accommodation region (7) by the screening device (10).

4. The apparatus according to claim 1, characterized in that the accommodation region (7) is matched to the outer shape of the at least one power source (8), and the screening device (10) is arranged between the inner wall of the accommodation region (7) and an outer wall of the power source (8).

5. The apparatus as claimed in claim 4, characterized in that the screening device (10) is of a housing element which accommodates the battery (8) and is composed of a magnetically screening metal, in particular μ-metal.

6. The apparatus according to claim 1, characterized in that the screening device (10) is a screening sleeve (12), in particular μ-metal sleeve, which has an open end.

7. The apparatus according to claim 1, characterized in that a closed end of the screening sleeve (12) is electrically conductively connected to a connection element (13) in the accommodation region (7).

8. The apparatus according to claim 1, characterized in that the accommodation region (7) is cylindrical and is provided for accommodating a cylindrical battery (8), and an open end of the accommodation region (7) can be closed by a screw cap (15).

9. The apparatus as claimed in claim 8, characterized in that the screening sleeve (12) is mounted in the accommodation region (7) in a longitudinally displaceable manner.

10. The apparatus according to claim 8, characterized in that the screening sleeve (12) is prestressed in a direction of the screw cap (15) by the connection element (13) which is in the form of a spring (16).

11. The apparatus according to claim 8, characterized in that the screw cap (15) has a cap element (19) which engages over an end of the screening sleeve (12).

12. The apparatus according to claim 8, characterized in that a first pole (20) of an inserted battery (8) makes electrical contact with an inner closed end (21) of the screening sleeve (12), and a second, opposite pole (22) of the battery (8) makes contact with at least one contact projection (23) of the screw cap (15).

13. The apparatus according to claim 8, characterized in that the screw cap (15) is surrounded by a sealing element, in particular by an O-ring seal (24).

14. The apparatus according to claim 8, characterized in that the screw cap (15) engages over approximately 10-50% of the length of the screening sleeve (12).

15. The apparatus according to claim 8, characterized by a contact spring (25) which surrounds the screening sleeve (12) at a distance and acts in a prestressing manner on an inner end of the screw cap (15).
